(19) United States
(12) Patent Application Publication
(10) Pub. No.: US 2024/0218513 A1
(43) Pub. Date: Jul. 4, 2024

(54) APPARATUS FOR TREATING SUBSTRATE AND METHOD FOR TREATING SUBSTRATE USING THE SAME

(71) Applicant: Samsung Display Co., LTD., Yongin-si (KR)

(72) Inventors: CHOELMIN JANG, Yongin-si (KR); MYUNGSOO HUH, Yongin-si (KR); KYUNGJOO MIN, Yongin-si (KR); MIN-GYU PARK, Yongin-si (KR)

(73) Assignee: Samsung Display Co., LTD., Yongin-si (KR)

(21) Appl. No.: 18/479,214

(22) Filed: Oct. 2, 2023

(30) Foreign Application Priority Data
Dec. 29, 2022 (KR) 10-2022-0189053

(51) Int. Cl. C23C 16/455; C23C 16/44

(52) U.S. Cl. CPC C23C 16/45561; C23C 16/4408; C23C 16/45544; C23C 16/45565

(57) ABSTRACT

An apparatus for treating a substrate includes a first gas pipe extending in a first direction and including a first injection part and a first exhaust part, a second gas pipe extending in the first direction, spaced apart from the first gas pipe in a second direction intersecting the first direction, and including a second injection part and a second exhaust part, multiple first gas connection pipes extending in the second direction, connected to the first gas pipe, and spaced apart from each other in the first direction, multiple second gas connection pipes extending in the second direction, connected to the second gas pipe, and spaced apart from each other in the first direction, and a gas supply adjacent to the plurality of first gas connection pipes and the plurality of second gas connection pipes.

### CROSS REFERENCE TO RELATED APPLICATION(S)

This application claims priority to and benefits of Korean Patent Application No. 10-2022-0189053 under 35 U.S.C. § 119, filed on Dec. 29, 2022, in the Korean Intellectual Property Office (KIPO), the entire contents of which are incorporated herein by reference.

### BACKGROUND

### 1. Technical Field

Embodiments relate to an apparatus for treating a substrate using a gas and a method for treating a substrate using the same.

### 2. Description of the Related Art

Semiconductor devices, display devices, electronic devices, or the like include multiple thin films. A method of forming the thin film includes a vapor deposition method. In the vapor deposition method, a source gas for forming the thin film and a reaction gas reacting with the source gas may be used. The vapor deposition method includes an atomic layer deposition (ALD).

In the atomic layer deposition method, the source gas and the reaction gas may be injected toward a substrate located in a chamber. The source gas and the reaction gas are adsorbed on the substrate to form an atomic layer.

### SUMMARY

The disclosure provides an apparatus for treating a substrate with improved process efficiency.

The disclosure also provides a method for treating a substrate using the apparatus for treating a substrate.

An apparatus for treating a substrate according to an embodiment of the disclosure may include a first gas pipe extending in a first direction and including a first injection part and a first exhaust part, a second gas pipe extending in the first direction, spaced apart from the first gas pipe in a second direction intersecting the first direction, and including a second injection part and a second exhaust part, a plurality of first gas connection pipes extending in the second direction, connected to the first gas pipe, and spaced apart from each other in the first direction, a plurality of second gas connection pipes extending in the second direction, connected to the second gas pipe, and spaced apart from each other in the first direction, and a gas supply adjacent to the plurality of first gas connection pipes and the plurality of second gas connection pipes.

In an embodiment, the plurality of first gas connection pipes and the plurality of second gas connection pipes may be alternately arranged in the first direction.

In an embodiment, each of the plurality of first gas connection pipes may include a plurality of first spray parts that spray a first gas in a third direction intersecting each of the first direction and the second direction, and each of the plurality of second gas connection pipes may include a plurality of second spray parts that spray a second gas in the third direction.

In an embodiment, the gas supply may include a plurality of third spray parts that spray a third gas in the third direction.

In an embodiment, each of the plurality of third spray parts may not overlap the plurality of first gas connection pipes and the plurality of second gas connection pipes in a plan view.

In an embodiment, each of the plurality of third spray parts may be disposed between one of the plurality of first gas connection pipes and one of the plurality of second gas connection pipes adjacent to each other in a plan view.

In an embodiment, each of the first gas pipe and the second gas pipe may be disposed on the plurality of first gas connection pipes and the plurality of second gas connection pipes.

In an embodiment, the gas supply may be disposed on the plurality of first gas connection pipes and the plurality of second gas connection pipes.

In an embodiment, the apparatus may further include at least one third gas pipe extending in the first direction, spaced apart from the first gas pipe and the second gas pipe in the second direction, and including a third injection part and a third exhaust part, and a plurality of third gas connection pipes extending in the second direction, connected to the at least one third gas pipe, and spaced apart from each other in the first direction.

In an embodiment, the plurality of first gas connection pipes, the plurality of second gas connection pipes, and the plurality of third gas connection pipes may be alternately arranged in the first direction.

In an embodiment, each of the plurality of third spray parts may not overlap the plurality of first gas connection pipes, the plurality of second gas connection pipes, and the plurality of third gas connection pipes in a plan view.

A method for treating a substrate according to an embodiment of the disclosure may include a first injection step of injecting a first gas into a first gas pipe, a second injection step of injecting a purge gas into the first gas pipe after the first injection step, a third injection step of injecting a second gas into a gas supply disposed adjacent to the first gas pipe after the second injection step, and a fourth injection step of injecting the purge gas into the gas supply after the third injection step.

In an embodiment, the first, second, third, and fourth injection steps may be repeatedly performed.

In an embodiment, the first injection step may further include injecting the purge gas into a second gas pipe facing the first gas pipe and the gas supply. The injecting of the first gas into the first gas pipe and the injecting of the purge gas into the second gas pipe and the gas supply may be performed simultaneously in the first injection step.

In an embodiment, the second injection step may further include exhausting the first gas from the first gas pipe and injecting the purge gas into a second gas pipe facing the first gas pipe and the gas supply. The exhausting of the first gas from the first gas pipe and the injecting of the purge gas into the first gas pipe, the second gas pipe, and the gas supply may be performed simultaneously in the second injection step.

In an embodiment, the third injection step may further include injecting the purge gas into the first gas pipe and a second gas pipe facing the first gas pipe. The injecting of the purge gas into the first gas pipe and the second gas pipe and the injecting of the second gas into the gas supply may be performed simultaneously in the third injection step.

In an embodiment, the fourth injection step may further include injecting the purge gas in the first gas pipe and a second gas pipe facing the first gas pipe and exhausting the second gas from the gas supply. The injecting of the purge gas into the first gas pipe, the second gas pipe, and the gas supply and the exhausting of the second gas from the gas supply may be performed simultaneously in the fourth injection step.

In an embodiment, the first gas and the purge gas injected in the first gas pipe may be sprayed through a plurality of first gas connection pipes connected to the first gas pipe and a plurality of first spray parts included in the plurality of first gas connection pipes, and the second gas and the purge gas injected into the gas supply may be sprayed through a plurality of second spray parts included in the gas supply.

In an embodiment, the method may further include a fifth injection step of injecting a third gas into a second gas pipe facing the first gas pipe after the fourth injection step.

In an embodiment, the third gas injected into the second gas pipe may be sprayed through a plurality of second gas connection pipes connected to the second gas pipe and a plurality of third spray parts included in the plurality of second gas connection pipes.

In an apparatus for treating a substrate according to embodiments of the disclosure, the apparatus for treating a substrate may include a shower head including first and second gas pipes spaced apart from each other in a first direction, a plurality of first gas connection pipes connected to the first gas pipe and a plurality of second gas connection pipes connected to the second gas pipe. The plurality of first gas connection pipes and the plurality of second gas connection pipes may be alternately disposed in the first direction. Each of the plurality of first gas connection pipes may include a plurality of first spray parts spraying a first gas, and each of the plurality of second gas connection pipes may include a plurality of second spray parts spraying a second gas. Accordingly, at least two types of gases may be sprayed from the shower head without cross-contamination. For example, since a multilayer thin film may be formed in a chamber by a shower head, process efficiency using the apparatus for treating a substrate may be improved.

### BRIEF DESCRIPTION OF THE DRAWINGS

FIG. 1 is a schematic front view illustrating an apparatus for treating a substrate according to an embodiment of the disclosure.

FIG. 2 is a schematic front cross-sectional view illustrating a shower head included in the apparatus for treating a substrate of FIG. 1.

FIG. 3 is a schematic plan view illustrating a first source pipe, a second source pipe, a first source connection pipe, and a second source connection pipe included in the shower head of FIG. 2.

FIG. 4 is a schematic cross-sectional perspective view taken along line I-I′ of FIG. 3.

FIG. 5 is a schematic front cross-sectional view taken along line II-II′ of FIG. 3.

FIG. 6 is a schematic front cross-sectional view taken along line III-III′ of FIG. 3.

FIG. 7 is a schematic side cross-sectional view taken along line IV-IV′ of FIG. 3.

FIG. 8 is a schematic side cross-sectional view taken along line V-V′ of FIG. 3.

FIG. 9 is a schematic plan view illustrating a reaction gas supply included in the shower head of FIG. 2.

FIG. 10 is a schematic cross-sectional perspective view taken along line IV-IV′ of FIG. 9.

FIG. 11 is a schematic bottom view illustrating the shower head included in the apparatus for treating a substrate of FIG. 1.

FIG. 12 is a flowchart of the steps of a method for treating a substrate using the apparatus for treating a substrate of FIG. 1.

FIG. 13 is a schematic front cross-sectional view illustrating a method for treating a substrate using the apparatus for treating a substrate of FIG. 1.

FIG. 14 is a schematic front cross-sectional view illustrating a method for treating a substrate using the apparatus for treating a substrate of FIG. 1.

FIG. 15 is a schematic front cross-sectional view illustrating a method for treating a substrate using the apparatus for treating a substrate of FIG. 1.

FIG. 16 is a schematic front cross-sectional view illustrating a method for treating a substrate using the apparatus for treating a substrate of FIG. 1.

FIG. 17 is a schematic front view illustrating an apparatus for treating a substrate according to another embodiment of the disclosure.

FIG. 18 is a schematic front cross-sectional view illustrating a shower head included in the apparatus for treating a substrate of FIG. 17.

FIG. 19 is a schematic plan view illustrating a first source pipe, a second source pipe, a third source pipe, a first source connection pipe, a second source connection pipe, and a third source connection pipe included in the shower head of FIG. 18.

FIG. 20 is a schematic bottom view illustrating the shower head included in the apparatus for treating a substrate of FIG. 17.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

When a component is described herein to “connect” another component to the other component or to be “connected to” other components, the components may be connected to each other as separate elements, or the components may be integral with each other.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a plane or on a plane or in a plan view” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, display devices in accordance with embodiments will be described in more detail with reference to the accompanying drawings. The same reference numerals are used for the same components in the drawings, and redundant descriptions of the same components will be omitted.

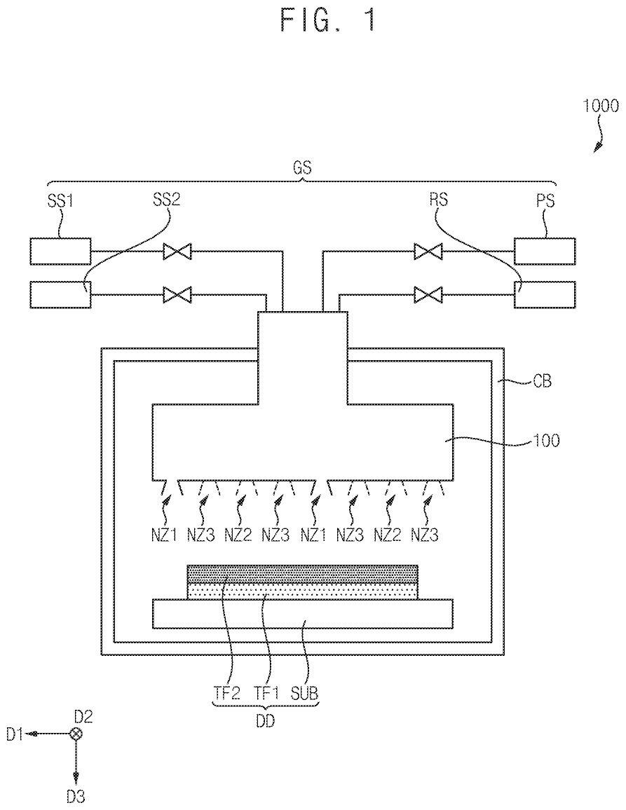

FIG. 1 is a schematic front view illustrating an apparatus 1000 for treating a substrate according to an embodiment of the disclosure.

Referring to FIG. 1, an apparatus 1000 for treating a substrate according to an embodiment of the disclosure may include a chamber CB, a shower head 100, and a gas storage GS. The gas storage GS may include a first source storage SS1, a second source storage SS2, a purge storage PS, and a reaction storage RS. Each of the first source storage SS1, the second source storage SS2, the purge storage PS, and the reaction storage RS may be formed in a tank shape.

The apparatus 1000 for treating a substrate may be used in a process of manufacturing a display device DD. For example, the apparatus 1000 for treating a substrate may be used in a deposition process. The display device DD may include a substrate SUB, a first thin film TF1, and a second thin film TF2. In an embodiment, each of the first thin film TF1 and the second thin film TF2 may be formed by an atomic layer deposition method. However, the disclosure is not limited thereto. For example, each of the first thin film TF1 and the second thin film TF2 may be a multi-component thin film. Each of the first thin film TF1 and the second thin film TF2 may be a thin film including an oxide of indium (In), gallium (Ga), zinc (Zn), aluminum (Al), zirconium (Zr), hafnium (Hf), the like, or a combination thereof.

In an embodiment, the chamber CB may accommodate the display device DD and the shower head 100. The gas storage GS may be located outside the chamber CB. In another embodiment, the chamber CB may further accommodate the gas storage GS.

In an embodiment, the chamber CB may be set to a condition for performing an atomic layer deposition. For example, the chamber CB may be set to a plasma state.

The shower head 100 may be disposed in the chamber CB. The shower head 100 may be spaced apart from the display device DD. For example, the display device DD may be spaced apart from the shower head 100 in a third direction D3.

The shower head 100 may be connected to the first source storage SS1, the second source storage SS2, the purge storage PS, and the reaction storage RS. The shower head 100 may include multiple spray nozzles. For example, the spray nozzles may include first spray nozzles (or first spray parts) NZ1, second spray nozzles (or second spray parts) NZ2, and third spray nozzles (or third spray parts) NZ3. The spray nozzles may be arranged in a first direction D1 intersecting the third direction D3. For example, the first direction D1 and the third direction D3 may be perpendicular to each other.

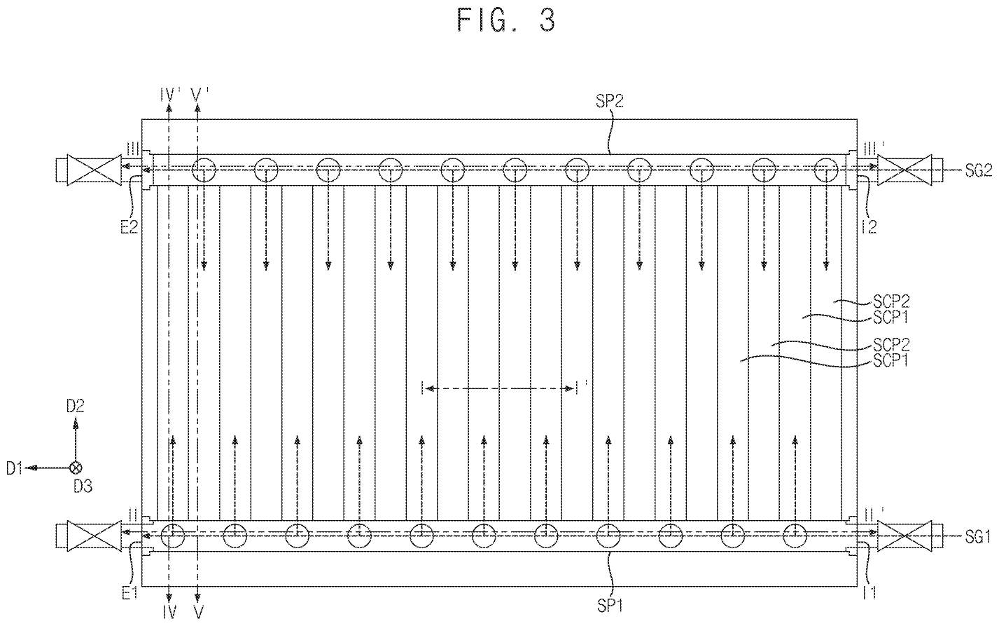

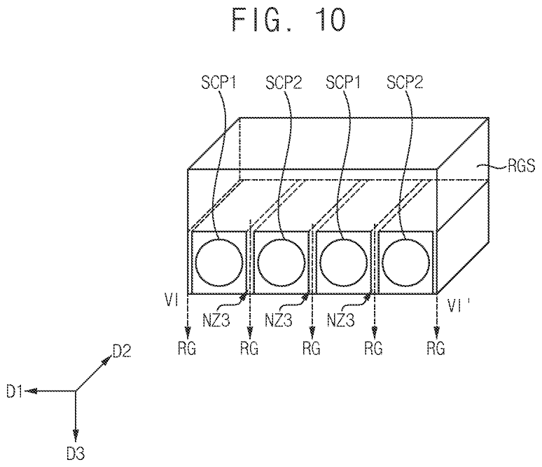

The shower head 100 may spray gas toward the substrate SUB in the third direction D3. For example, the shower head 100 may spray a first source gas (or a first gas, see, e.g., a first source gas SG1 of FIG. 3) through the first spray nozzles NZ1, may spray a second source gas (or a second gas, see, e.g., a second source gas SG2 of FIG. 3) through the second spray nozzles NZ2, and may spray a reaction gas (see, e.g., a reaction gas RG of FIG. 10) through the third spray nozzles NZ3.

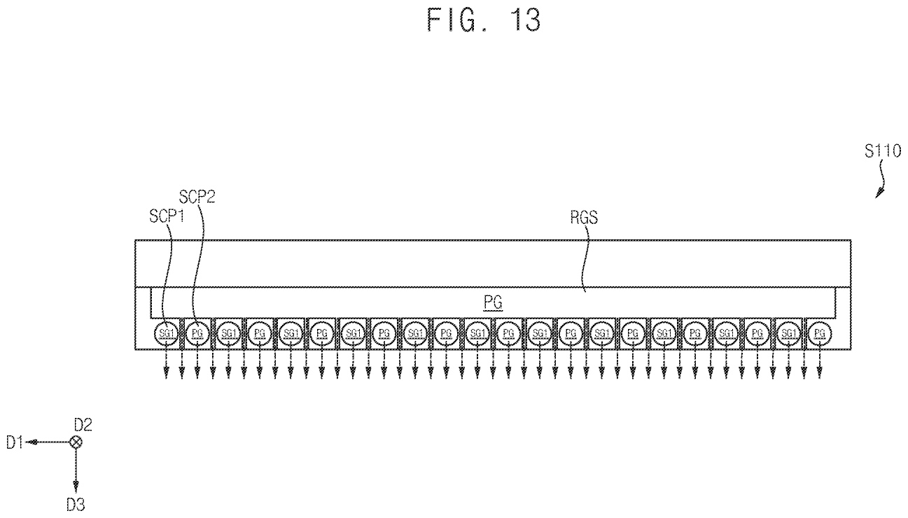

The first source storage SS1 connected to the shower head 100 may inject the first source gas into the shower head 100. The second source storage SS2 connected to the shower head 100 may inject the second source gas into the shower head 100. The purge storage PS connected to the shower head 100 may inject a purge gas (see, e.g., a purge gas PG of FIG. 13) into the shower head 100. The reaction storage RS connected to the shower head 100 may inject the reaction gas into the shower head 100.

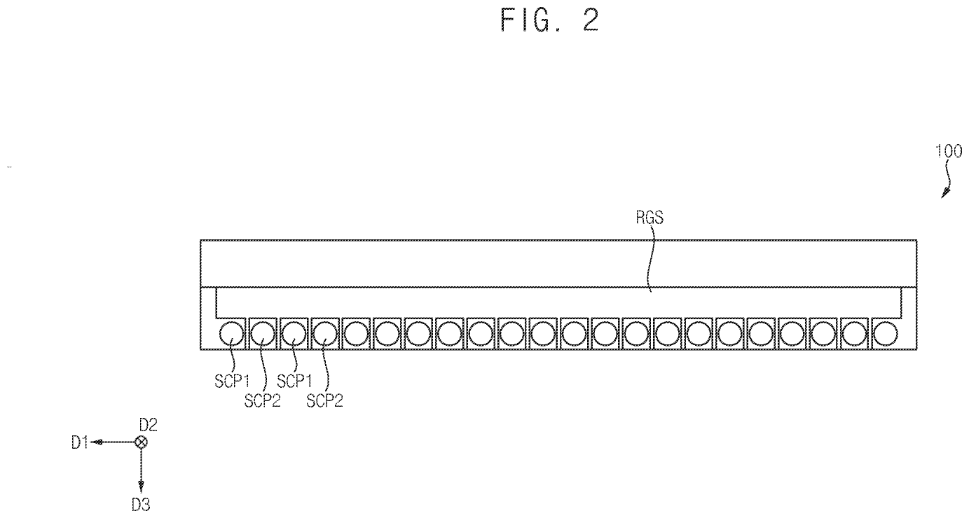

FIG. 2 is a schematic front cross-sectional view illustrating a shower head 100 included in the apparatus 1000 for treating a substrate of FIG. 1.

Referring to FIG. 2, the shower head 100 may include multiple first source connection pipes (or first gas connection pipes) SCP1, multiple second source connection pipes (or second gas connection pipes) SCP2, and a reaction gas supply RGS.

In an embodiment, the first source connection pipes SCP1 and the second source connection pipes SCP2 may be repeatedly (or alternately) arranged in the first direction D1. The first source connection pipes SCP1 may be spaced apart from each other in the first direction DR1, and the second source connection pipes SCP2 may be spaced apart from each other in the first direction DR1. For example, the first source connection pipes SCP1 and the second source connection pipes SCP2 may be alternately arranged in the first direction D1.

Each of the first source connection pipes SCP1 and the second source connection pipes SCP2 may extend in a second direction D2 intersecting each of the first direction D1 and the third direction D3. For example, the second direction D2 may be perpendicular to each of the first direction D1 and the third direction D3.

The reaction gas supply RGS may be disposed adjacent to the first source connection pipes SCP1 and the second source connection pipes SCP2. For example, the reaction gas supply RGS may be disposed on the first source connection pipes SCP1 and the second source connection pipes SCP2. However, the disclosure is not limited thereto. In another embodiment, the reaction gas supply RGS may be disposed below the first source connection pipes SCP1 and the second source connection pipes SCP2.

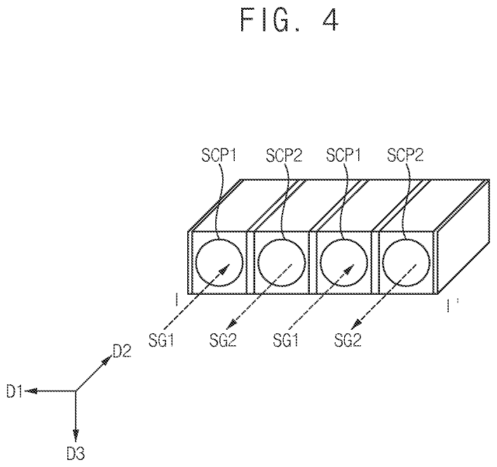

FIG. 3 is a schematic plan view illustrating a first source pipe (or a first gas pipe) SP1, a second source pipe (or a second gas pipe) SP2, a first source connection pipe (or a first gas connection pipe) SCP1, and a second source connection pipe (or a second gas connection pipe) SCP2 included in the shower head 100 of FIG. 2. FIG. 4 is a schematic cross-sectional perspective view taken along line I-I′ of FIG. 3. For example, FIG. 4 may be a schematic cross-sectional view of the first source connection pipes SCP1 and the second source connection pipes SCP2.

Referring to FIGS. 2 to 4, the shower head 100 may include a first source pipe SP1, a second source pipe SP2, the first source connection pipe SCP1, and the second source connection pipe SCP2.

The first source pipe SP1 may extend in the first direction D1. The first source pipe SP1 may include a first injection part I1 and a first exhaust part E1 spaced apart from the first injection part I1 in the first direction DR1. For example, the first injection part I1 may be disposed on a first end of the first source pipe SP1, and the first exhaust part E1 may be disposed on a second end facing the first end of the first source pipe SP1. A valve may be installed on each of the first injection part I1 and the first exhaust part E1. The valve may be open or closed. In an embodiment, a first source gas SG1 may be injected into the first source pipe SP1 through the first injection part I1, and may be exhausted from the first source pipe SP1 through the first exhaust part E1. For example, the first source gas SG1 may include aluminum (Al), zinc (Zn), zirconium (Zr), hafnium (Hf), titanium (Ti), the like, or a combination thereof.

The first source pipe SP1 may be connected to each of the first source connection pipes SCP1. Accordingly, the first source gas SG1 injected through the first injection part I1 may be injected into each of the first source connection pipes SCP1. For example, the first source gas SG1 may be injected into each of the first source connection pipes SCP1 in the second direction D2, and the valve installed on the first injection part I1 may be opened, and the valve installed on the first exhaust part E1 may be closed.

The second source pipe SP2 may be spaced apart from the first source pipe SP1 in the second direction D2. The second source pipe SP2 may extend in the first direction D1. The second source pipe SP2 may include a second injection part I2 and a second exhaust part E2 spaced apart from the second injection part I2 in the first direction DR1. For example, the second injection part I2 may be disposed on a first end of the second source pipe SP2, and the second exhaust part E2 may be disposed on a second end facing the first end of the second source pipe SP2. A valve may be installed on each of the second injection part I2 and the second exhaust part E2. The valve may be open or closed. In an embodiment, a second source gas SG2 may be injected into the second source pipe SP2 through the second injection part I2, and may be exhausted from the second source pipe SP2 through the second exhaust part E2. For example, the second source gas SG2 may include aluminum (Al), zinc (Zn), zirconium (Zr), hafnium (Hf), titanium (Ti), the like, or a combination thereof.

The second source pipe SP2 may be connected to each of the second source connection pipes SCP2. Accordingly, the second source gas SG2 injected through the second injection part I2 may be injected into each of the second source connection pipes SCP2. For example, the second source gas SG2 may be injected into each of the second source connection pipes SCP2 in a direction opposite to the second direction D2, and the valve installed on the second injection part I2 may be opened, and the valve installed on the second exhaust part E2 may be closed.

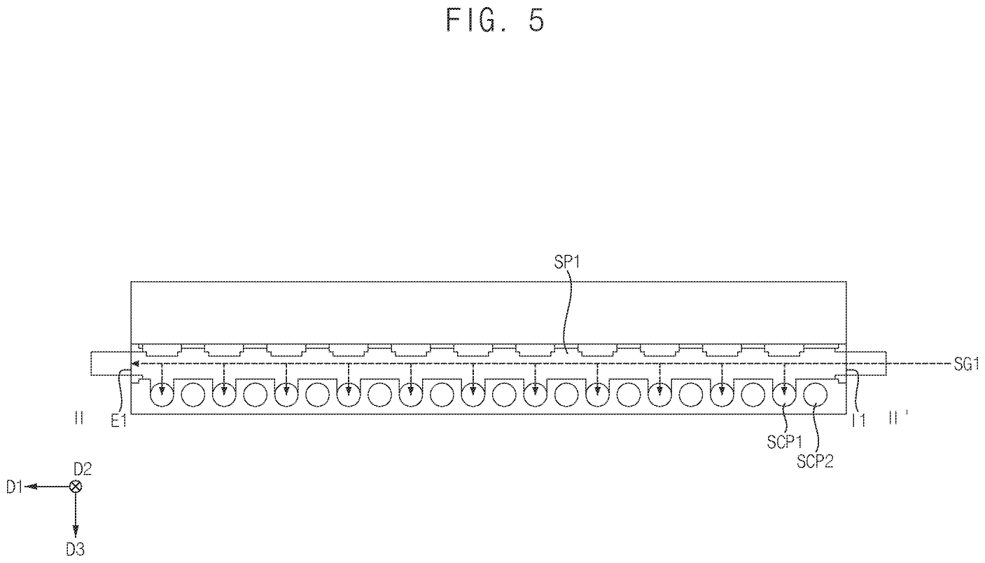

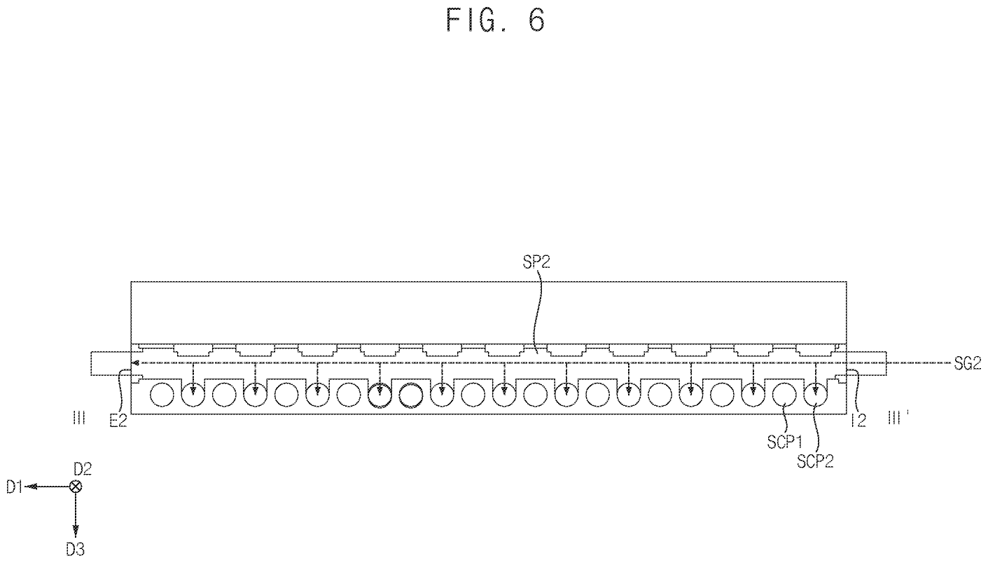

FIG. 5 is a schematic front cross-sectional view taken along line II-II′ of FIG. 3. FIG. 6 is a schematic front cross-sectional view taken along line III-III′ of FIG. 3. For example, FIG. 5 may be a schematic cross-sectional view of the first source pipe SP1, and FIG. 6 may be a schematic cross-sectional view of the second source pipe SP2.

Referring to FIGS. 5 and 6, the first source pipe SP1 may be connected to the first source connection pipes SCP1 through multiple holes formed on a surface of the first source pipe SP1. The second source pipe SP2 may be connected to the second source connection pipes SCP2 through multiple holes formed on a surface of the second source pipe SP2.

For example, the first source gas SG1 may be injected into the first source connection pipes SCP1 through the holes formed on the surface of the first source pipe SP1. The second source gas SG2 may be injected into the second source connection pipes SCP2 through the holes formed on the surface of the second source pipe SP2.

In an embodiment, each of the first source pipe SP1 and the second source pipe SP2 may be disposed on the first source connection pipes SCP1 and the second source connection pipes SCP2. However, the disclosure is not limited thereto. In another embodiment, each of the first source pipe SP1 and the second source pipe SP2 may be disposed below the first source connection pipes SCP1 and the second source connection pipes SCP2.

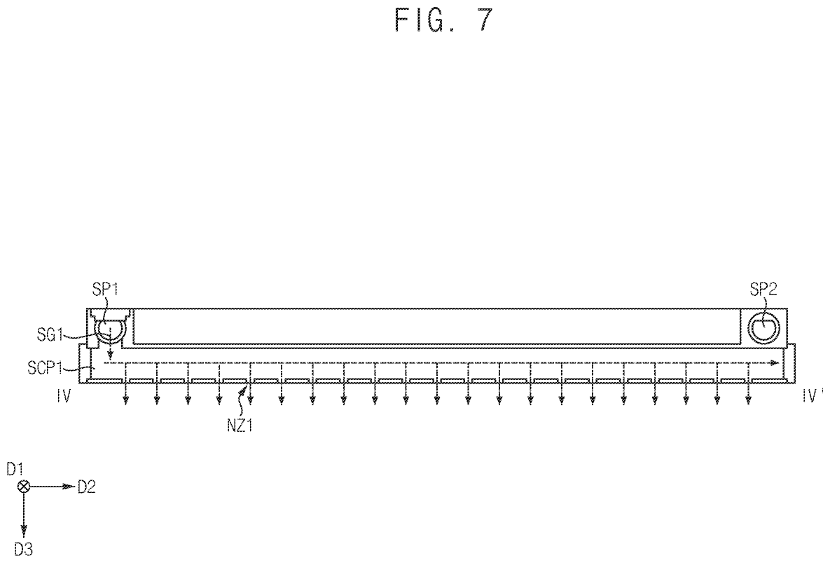

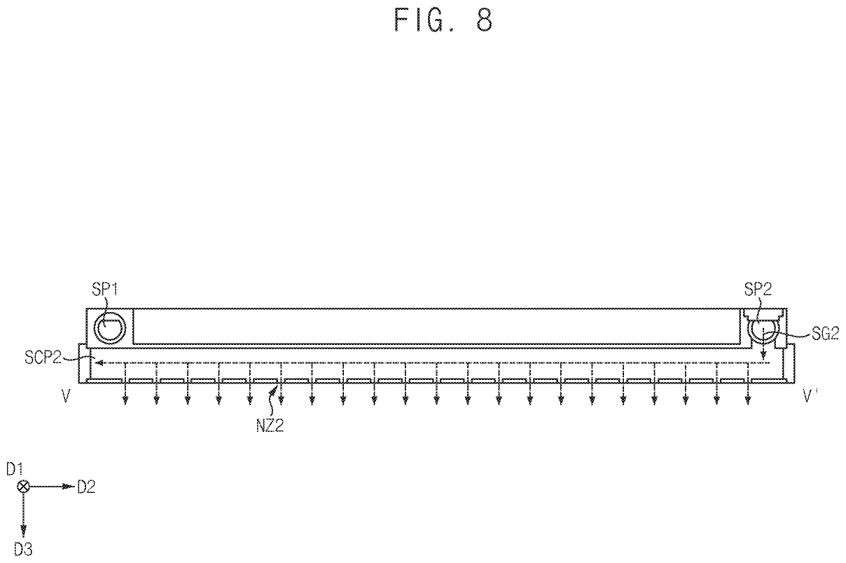

FIG. 7 is a schematic side cross-sectional view taken along line IV-IV′ of FIG. 3. FIG. 8 is a schematic side cross-sectional view taken along line V-V′ of FIG. 3. For example, FIG. 7 may be a schematic cross-sectional view of the first source connection pipe SCP1, and FIG. 8 may be a schematic cross-sectional view of the second source connection pipe SCP2.

Referring to FIGS. 1, 3, 7, and 8, each of the first source connection pipes SCP1 may include the first spray nozzles NZ1. Each of the second source connection pipes SCP2 may include the second spray nozzles NZ2.

The first spray nozzles NZ1 may be repeatedly arranged on the first source connection pipe SCP1 in the second direction D2, and the second spray nozzles NZ2 may be repeatedly arranged on the second source connection pipe SCP2 in the second direction D2. Each of the first spray nozzles NZ1 may spray the first source gas SG1 toward the third direction D3. Each of the second spray nozzles NZ2 may spray the second source gas SG2 toward the third direction D3.

For example, the first source gas SG1 injected into each of the first source connection pipes SCP1 through the first source pipe SP1 may be sprayed into the chamber CB through the first spray nozzles NZ1. The second source gas SG2 injected into each of the second source connection pipes SCP2 through the second source pipe SP2 may be sprayed into the chamber CB through the second spray nozzles NZ2.

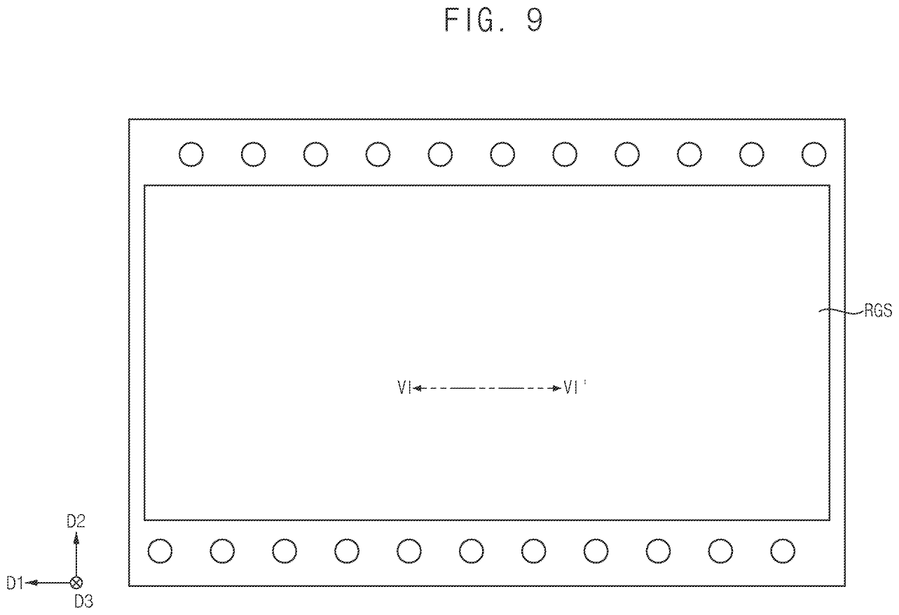

FIG. 9 is a schematic plan view illustrating a reaction gas supply RGS included in the shower head 100 of FIG. 2. FIG. 10 is a schematic cross-sectional perspective view taken along line IV-IV′ of FIG. 9.

Referring to FIGS. 1, 2, 9, and 10, a reaction gas RG may be injected to the reaction gas supply RGS. For example, the reaction gas RG may include nitrogen (N₂), oxygen (O₂), nitrous oxide (N₂O), ammonia (NH₃), ozone (O₃), the like, or a combination thereof.

The reaction gas supply RGS may include the third spray nozzles NZ3. The third spray nozzles NZ3 may be repeatedly arranged in the first direction D1 and the second direction D2. The third spray nozzles NZ3 may spray the reaction gas RG toward the third direction D3. For example, the reaction gas RG injected into the reaction gas supply RGS may be sprayed into the chamber CB through the third spray nozzles NZ3.

In an embodiment, the third spray nozzles NZ3 may not overlap (or offset from) the first source connection pipes SCP1 and the second source connection pipes SCP2 in a plan view. For example, each of the third spray nozzles NZ3 may be disposed between the first source connection pipe SCP1 and the second source connection pipe SCP2 adjacent to each other in a plan view. For example, the reaction gas RG may be sprayed between the first source connection pipe SCP1 and the second source connection pipe SCP2 adjacent to each other through the third spray nozzles NZ3.

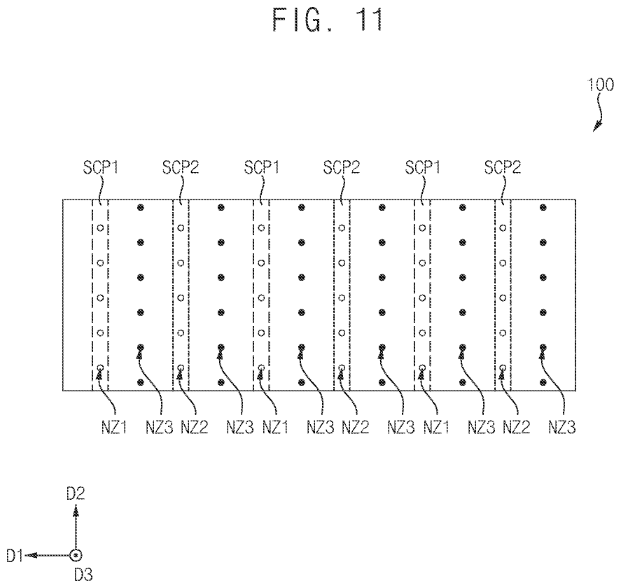

FIG. 11 is a schematic bottom view illustrating the shower head 100 included in the apparatus 1000 for treating a substrate of FIG. 1.

Referring to FIG. 11, the shower head 100 may include the first source connection pipes SCP1, the second source connection pipes SCP2, the first spray nozzles NZ1, the second spray nozzles NZ2, and the third spray nozzles NZ3.

The first source connection pipes SCP1 and the second source connection pipes SCP2 may be alternately arranged in the first direction D1.

Each of the first source connection pipes SCP1 and the second source connection pipes SCP2 may extend in the second direction D2. The first spray nozzles NZ1 included in each of the first source connection pipes SCP1 may be arranged in the second direction D2. The second spray nozzles NZ2 included in each of the second source connection pipes SCP2 may be arranged in the second direction D2.

Each of the third spray nozzles NZ3 may be disposed between the first source connection pipe SCP1 and the second source connection pipe SCP2 adjacent to each other in a plan view. Each of the third spray nozzles NZ3 may be disposed between the first spray nozzle NZ1 and the second spray nozzle NZ2 adjacent to each other in a plan view (or a bottom view).

The apparatus 1000 for treating a substrate according to an embodiment of the disclosure may include the shower head 100 including the first source pipe SP1 and the second source pipe SP2 spaced apart from each other in the first direction DR1, the first source connection pipes SCP1 connected to the first source pipe SP1, and the second source connection pipes SCP2 connected to the second source pipe SP2. The first source connection pipes SCP1 and the second source connection pipes SCP2 may be alternately arranged in the first direction DR1. Each of the first source connection pipes SCP1 may include the first spray nozzles NZ1 that spray the first source gas SG1 (see, e.g. FIGS. 3 and 4), and each of the second source connection pipes SCP2 may include the second spray nozzles NZ2 that spray the second source gas SG2 (see, e.g., FIGS. 3 and 4). Accordingly, two or more types of source gases may be sprayed from the shower head 100 without cross-contamination. For example, since multiple thin film layers may be formed in one chamber CB through one shower head 100, process efficiency using the apparatus 1000 for treating a substrate may be improved.

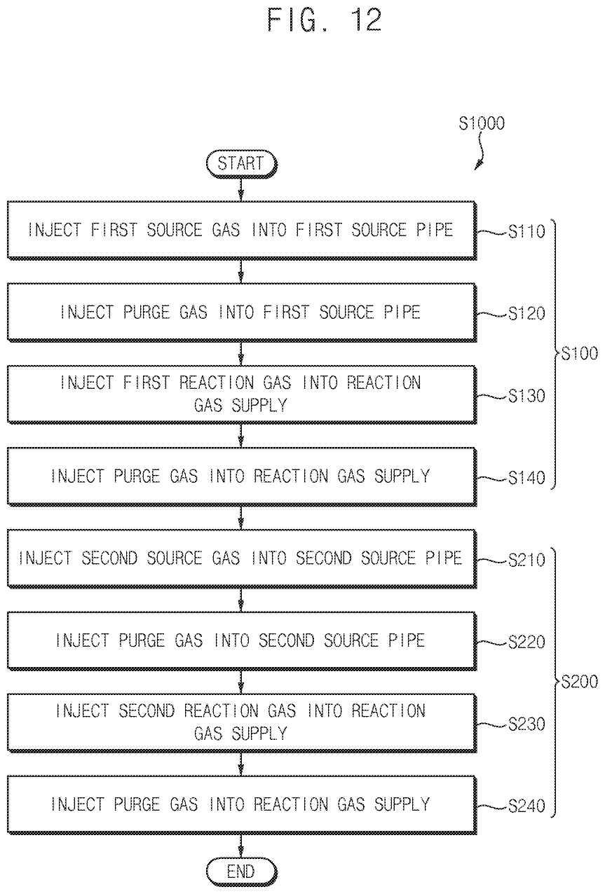

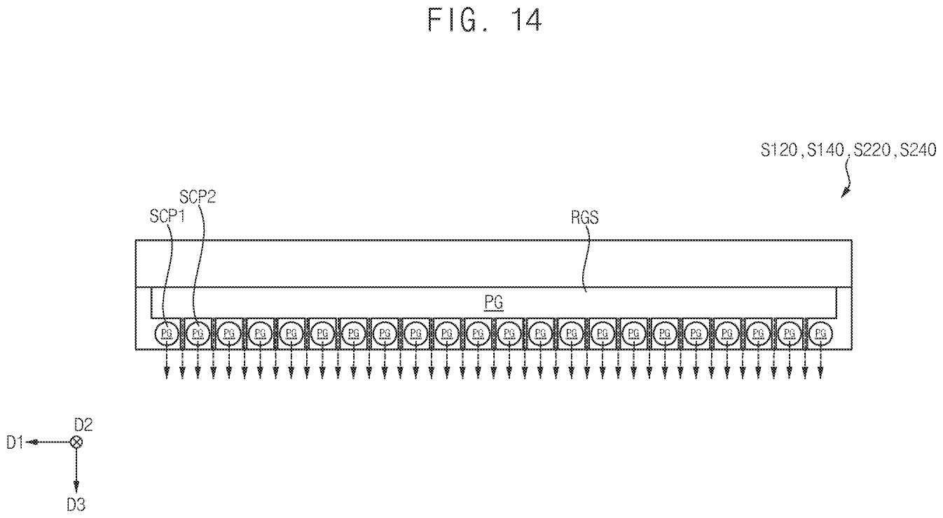

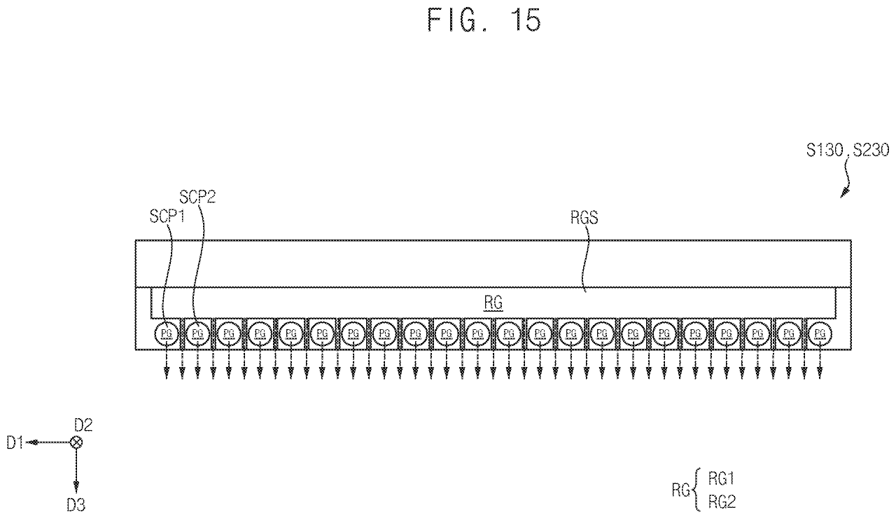

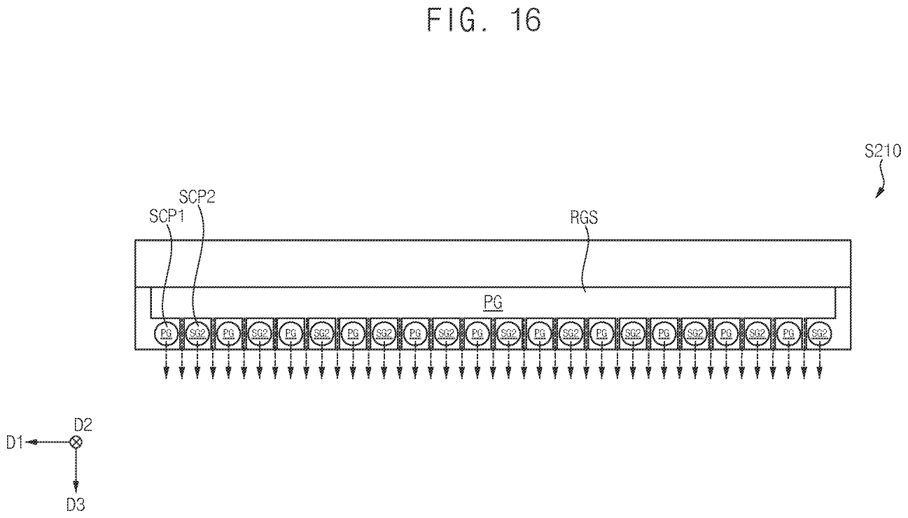

FIG. 12 is a flowchart of the steps of a method for treating a substrate using the apparatus 1000 for treating a substrate of FIG. 1. FIGS. 13 to 16 are schematic front cross-sectional views illustrating a method for treating a substrate using the apparatus 1000 for treating a substrate of FIG. 1.

FIGS. 12 to 16 are schematic views illustrating the method for treating a substrate using the apparatus 1000 for treating a substrate of FIG. 1.

A method (S1000) for treating a substrate described with reference to FIGS. 12 to 16 may be performed using the apparatus 1000 for treating a substrate described with reference to FIGS. 1 to 11. Therefore, redundant descriptions will be omitted or simplified.

Referring to FIGS. 1, 3, 4, and 10 to 16, in the method S1000 for treating a substrate using the apparatus 1000 for treating a substrate, a first thin film TF1 may be formed on the substrate SUB (S100). After forming the first thin film TF1 (S100), a second thin film TF2 may be formed on the first thin film TF1 (S200).

In an embodiment, the forming of the first thin film TF1 (S100) and the forming of the second thin film TF2 (S200) may be repeatedly (or alternately) performed. For example, the first thin film TF1 and the second thin film TF2 may be repeatedly (or alternately) formed on the substrate SUB in the third direction DR3.

The forming of the first thin film TF1 (S100) may include first, second, third, and fourth injection steps (S110, S120, S130, and S140).

In the forming of the first thin film TF1 (S100), the first source gas SG1 may be injected into the first source pipe SP1 (S110). For example, the first injection step (S110) may include injecting the first source gas (or the first gas) SG1 into the first source pipe SP1, and injecting the purge gas PG into each of the second source pipe SP2 and the reaction gas supply RGS.

Accordingly, the first source gas SG1 may be injected into the first source connection pipes SCP1, and the first source gas SG1 may be sprayed from the first spray nozzles NZ1. The purge gas PG may be injected into the second source connection pipes SCP2, and the purge gas PG may be sprayed from the second spray nozzles NZ2. The purge gas PG may be sprayed from the third spray nozzles NZ3.

In an embodiment, in the first injection step (S110), the injecting of the first source gas SG1 into the first source pipe SP1 and the injecting of the purge gas PG into each of the second source pipe SP2 and the reaction gas supply RGS may be performed simultaneously.

In the forming of the first thin film TF1 (S100), the purge gas PG may be injected into the first source pipe SP1 (S120). For example, the second injection step (S120) may include injecting the purge gas PG into each of the first source pipe SP1, the second source pipe SP2, and the reaction gas supply RGS and exhausting the first source gas SG1 from the first source pipe SP1.

Accordingly, the purge gas PG may be injected into the first source connection pipes SCP1, and the purge gas PG may be sprayed from the first spray nozzles NZ1. The purge gas PG may be injected into the second source connection pipes SCP2, and the purge gas PG may be sprayed from the second spray nozzles NZ2. The purge gas PG may be sprayed from the third spray nozzles NZ3.

In an embodiment, in the second injection step (S120), the exhausting of the first source gas SG1 from the first source pipe SP1 and the injecting of the purge gas PG into each of the first source pipe SP1, the second source pipe SP2, and the reaction gas supply RGS may be performed simultaneously. For example, as the purge gas PG is injected through the first injection part I1 of the first source pipe SP1, the first source gas SG1 may be exhausted through first exhaust part E1 of the first source pipe SP1.

In the forming of the first thin film TF1 (S100), a first reaction gas RG1 may be injected into the reaction gas supply RGS (S130). For example, the third injection step (S130) may include injecting the purge gas PG into each of the first source pipe SP1 and the second source pipe SP2, and injecting the first reaction gas RG1 into the reaction gas supply RGS.

Accordingly, the purge gas PG may be injected into the first source connection pipes SCP1, and the purge gas PG may be sprayed from the first spray nozzles NZ1. The purge gas PG may be injected into the second source connection pipes SCP2, and the purge gas PG may be sprayed from the second spray nozzles NZ2. The first reaction gas RG1 may be sprayed from the third spray nozzles NZ3.

In an embodiment, in the third injection step (S130), the injecting of the purge gas PG into each of the first source pipe SP1 and the second source pipe SP2 and the injecting of the first reaction gas RG1 into the reaction gas supply RGS may be performed simultaneously.

In the forming of the first thin film TF1 (S100), the purge gas PG may be injected into the reaction gas supply RGS (S140). For example, the fourth injection step (S140) may include injecting the purge gas PG into each of the first source pipe SP1, the second source pipe SP2, and the reaction gas supply RGS and exhausting the first reaction gas RG1 from the reaction gas supply RGS.

Accordingly, the purge gas PG may be injected into the first source connection pipes SCP1, and the purge gas PG may be sprayed from the first spray nozzles NZ1. The purge gas PG may be injected into the second source connection pipes SCP2, and the purge gas PG may be sprayed from the second spray nozzles NZ2. The purge gas PG may be sprayed from the third spray nozzles NZ3.

In an embodiment, in the fourth injection step (S140), the injecting of the purge gas PG into each of the first source pipe SP1, the second source pipe SP2, and the reaction gas supply RGS and the exhausting of the first reaction gas RG1 from the reaction gas supply RGS may be performed simultaneously. For example, as the purge gas PG is injected into the reaction gas supply RGS, the first reaction gas RG1 may be exhausted from the reaction gas supply RGS.

In an embodiment, the first, second, third, and fourth injection steps (S110, S120, S130, and S140) may be performed at different times. For example, the first, second, third, and fourth injection steps (S110, S120, S130, and S140) may be sequentially performed. The second injection step (S120) may be performed after the first injection step (S110). The third injection step (S130) may be performed after the second injection step (S120). The fourth injection step (S140) may be performed after the third injection step (S130).

The first source gas SG1 and the first reaction gas RG1 may be sequentially sprayed from the shower head 100 through the first, second, third, and fourth injection steps (S110, S120, S130, and S140). In other words, the first source gas SG1 and the first reaction gas RG1 may be sequentially deposited on the substrate SUB. Accordingly, the first thin film TF1 may be formed on the substrate SUB.

In an embodiment, the first, second, third, and fourth injection steps (S110, S120, S130, and S140) may be repeatedly performed. Accordingly, a thickness of the first thin film TF1 may be adjusted.

The forming of the second thin film TF2 (S200) may include fifth, sixth, seventh, and eighth injection steps (S210, S220, S230, and S240).

In the forming of the second thin film TF2 (S200), the second source gas (or the second gas) SG2 may be injected into the second source pipe SP2 (S210). For example, the fifth injection step (S210) may include injecting the second source gas (or a third gas) SG2 into the second source pipe SP2, and injecting the purge gas PG into each of the first source pipe SP1 and the reaction gas supply RGS.

Accordingly, the second source gas SG2 may be sprayed from the second spray nozzles NZ2, and the purge gas PG may be sprayed from each of the first spray nozzles NZ1 and the third spray nozzles NZ3.

In an embodiment, in the fifth injection step (S210), the injecting of the second source gas SG2 into the second source pipe SP2 and the injecting of the purge gas PG into each of the first source pipe SP1 and the reaction gas supply RGS may be performed simultaneously.

In the forming of the second thin film TF2 (S200), the purge gas PG may be injected into the second source pipe SP2 (S220). For example, the sixth injection step (S220) may include injecting purge gas PG into each of the first source pipe SP1, the second source pipe SP2, and the reaction gas supply RGS and exhausting the second source gas SG2 from the second source pipe SP2.

Accordingly, the purge gas PG may be sprayed from each of the first spray nozzles NZ1, the second spray nozzles NZ2, and the third spray nozzles NZ3.

In an embodiment, in the sixth injection step (S220), the exhausting of the second source gas SG2 from the second source pipe SP2 and the injecting of the purge gas PG into each of the first source pipe SP1, the second source pipe SP2, and the reaction gas supply RGS may be performed simultaneously. For example, as the purge gas PG is injected through the second injection part I2 of the second source pipe SP2, the second source gas SG2 may be exhausted through the second exhaust part E2 of the second source pipe SP2.

In the forming of the second thin film TF2 (S200), a second reaction gas RG2 may be injected into the reaction gas supply RGS (S230). For example, the seventh injection step (S230) may include injecting the purge gas PG into each of the first source pipe SP1 and the second source pipe SP2, and injecting the second reaction gas RG2 into the reaction gas supply RGS.

Accordingly, the purge gas PG may be sprayed from each of the first spray nozzles NZ1 and the second spray nozzles NZ2, and the second reaction gas RG2 may be sprayed from the third spray nozzles NZ3.

In an embodiment, in the seventh injection step (S230), the injecting of the purge gas PG into each of the first source pipe SP1 and the second source pipe SP2 and the injecting of the second reaction gas RG2 into the reaction gas supply RGS may be performed simultaneously.

In an embodiment, the first reaction gas RG1 and the second reaction gas RG2 may include a same material. In another embodiment, the first reaction gas RG1 and the second reaction gas RG2 may include different materials.

In the forming of the second thin film TF2 (S200), the purge gas PG may be injected into the reaction gas supply RGS (S240). For example, the eighth injection step (S240) may include injecting the purge gas PG into each of the first source pipe SP1, the second source pipe SP2, and the reaction gas supply RGS and exhausting the second reaction gas RG2 from the reaction gas supply RGS.

Accordingly, the purge gas PG may be sprayed from each of the first spray nozzles NZ1, the second spray nozzles NZ2, and the third spray nozzles NZ3.

In an embodiment, in the eighth injection step (S240), the injecting of the purge gas PG into each of the first source pipe SP1, the second source pipe SP2, and the reaction gas supply RGS and the exhausting of the second reaction gas RG2 from the reaction gas supply RGS may be performed simultaneously. For example, as the purge gas PG is injected into the reaction gas supply RGS, the second reaction gas RG2 may be exhausted from the reaction gas supply RGS.

In an embodiment, the fifth, sixth, seventh, and eighth injection steps (S210, S220, S230, and S240) may be performed at different times. For example, the fifth, sixth, seventh, and eighth injection steps (S210, S220, S230, and S240) may be sequentially performed. For example, the sixth injection step (S220) may be performed after the fifth injection step (S210). The seventh injection step (S230) may be performed after the sixth injection step (S220). The eighth injection step (S240) may be performed after the seventh injection step (S230).

The second source gas SG2 and the second reaction gas RG2 may be sequentially sprayed from the shower head 100 through the fifth, sixth, seventh, and eighth injection steps (S210, S220, S230, and S240). In other words, the second source gas SG2 and the second reaction gas RG2 may be sequentially deposited on the substrate SUB. Accordingly, the second thin film TF2 may be formed on the first thin film TF1.

In an embodiment, the fifth, sixth, seventh, and eighth injection steps (S210, S220, S230, and S240) may be repeatedly performed. Accordingly, a thickness of the second thin film TF2 may be adjusted.

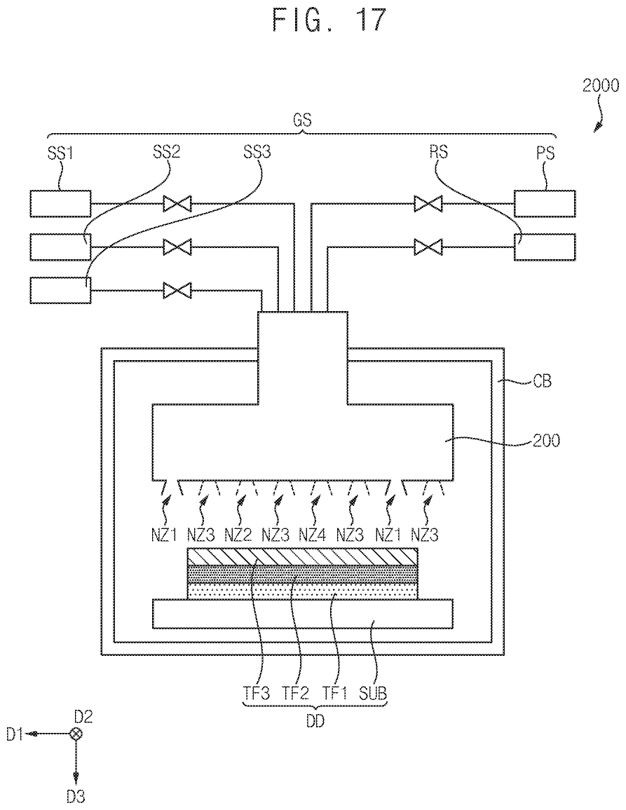

FIG. 17 is a schematic front view illustrating an apparatus 2000 for treating a substrate according to another embodiment of the disclosure.

Referring to FIG. 17, an apparatus 2000 for treating a substrate according to an embodiment of the disclosure may include a chamber CB, a shower head 200, and a gas storage GS. The gas storage GS may include a first source storage SS1, a second source storage SS2, a third source storage SS3, a purge storage PS, and a reaction storage RS.

Hereinafter, descriptions of the apparatus 1000 for treating a substrate described with reference to FIG. 1 will be omitted or simplified.

The apparatus 2000 for treating a substrate may be used in a process of manufacturing a display device DD. The display device DD may include a substrate SUB, a first thin film TF1, a second thin film TF2, and a third thin film TF3. In an embodiment, each of the first thin film TF1, the second thin film TF2, and the third thin film TF3 may be formed by an atomic layer deposition method.

The shower head 200 may be connected to the first source storage SS1, the second source storage SS2, the third source storage SS3, the purge storage PS, and the reaction storage RS, and may include multiple spray nozzles. For example, the spray nozzles may include first spray nozzles (or first spray parts) NZ1, second spray nozzles (or second spray parts) NZ2, third spray nozzles (or third spray parts) NZ3, and fourth spray nozzles (or fourth spray parts) NZ4.

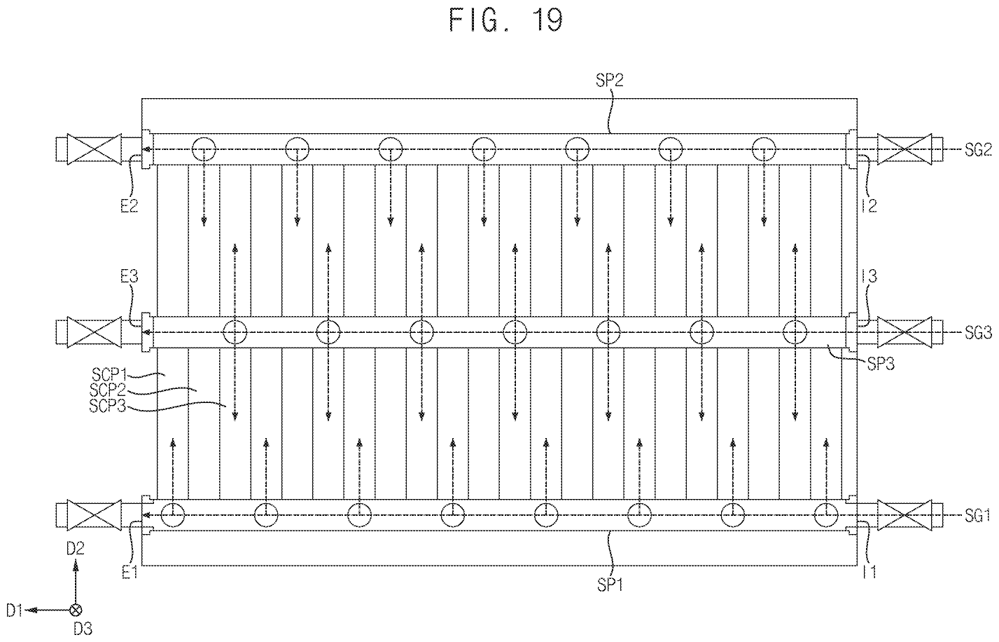

The shower head 200 may spray gas toward the substrate SUB in the third direction D3. For example, the shower head 200 may spray a first source gas (see, e.g., a first source gas SG1 of FIG. 19) through the first spray nozzles NZ1, may spray a second source gas (see, e.g., a second source gas SG2 of FIG. 19) through the second spray nozzles NZ2, may spray a reaction gas (see, e.g., the reaction gas RG of FIG. 10) through the third spray nozzles NZ3, and may spray a third source gas (or a third gas, see, e.g., a third source gas SG3 of FIG. 19) through the fourth spray nozzles NZ4.

Although FIG. 17 illustrates that the display device DD includes three thin films TF1. TF2, and TF3, the disclosure is not limited thereto. For example, the display device DD may include four or more thin films, the apparatus 2000 for treating a substrate may include four or more gas storages, and the shower head 200 may include five or more spray nozzles.

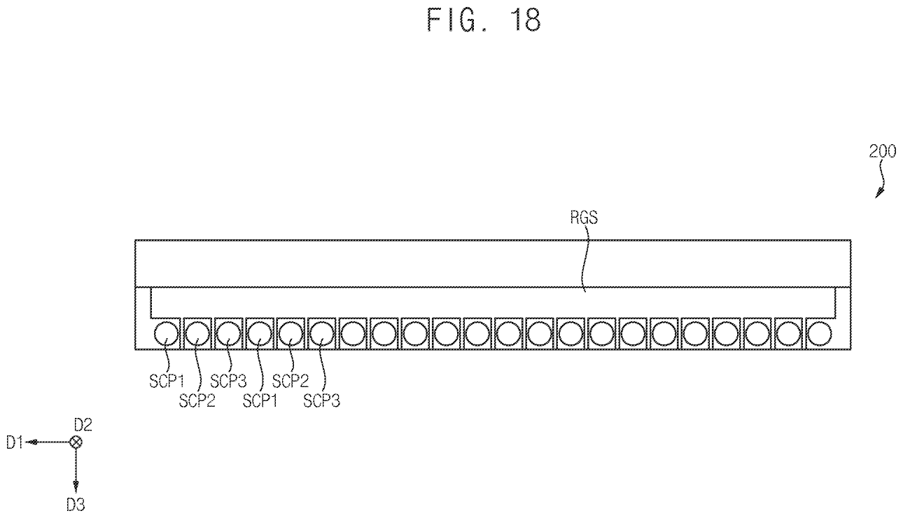

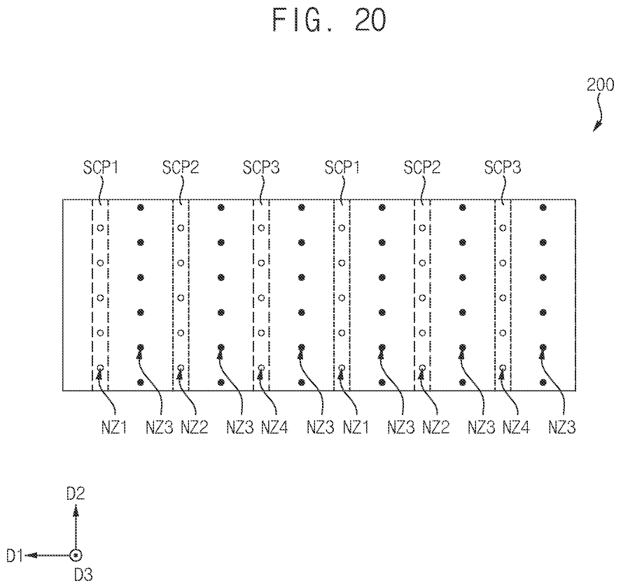

FIG. 18 is a schematic front cross-sectional view illustrating a shower head 200 included in the apparatus 2000 for treating a substrate of FIG. 17. FIG. 19 is a schematic plan view illustrating a first source pipe (or a first gas pipe) SP1, a second source pipe (or a second gas pipe) SP2, a third source pipe (or a third gas pipe) SP3, a first source connection pipe (or a first gas connection pipe) SCP1, a second source connection pipe (or a second gas connection pipe) SCP2, and a third source connection pipe (or a third gas connection pipe) SCP3 included in the shower head 200 of FIG. 18. FIG. 20 is a schematic bottom view illustrating the shower head 200 included in the apparatus 2000 for treating a substrate of FIG. 17.

Referring to FIGS. 17 to 20, the shower head 200 may include a first source pipe SP1, a second source pipe SP2, at least one third source pipe SP3, multiple first source connection pipes (or first gas connection pipes) SCP1, multiple second source connection pipes (or second gas connection pipes) SCP2, multiple third source connection pipes (or third gas connection pipes) SCP3, and a reaction gas supply RGS.

Hereinafter, descriptions overlapping with the shower head 100 described with reference to FIGS. 2 to 11 will be omitted or simplified.

In an embodiment, the third source connection pipes SCP3 may be repeatedly arranged in the first direction D1. Each of the third source connection pipes SCP3 may extend in the second direction D2. The third source connection pipes SCP3 may be spaced apart from each other in the first direction DR1. For example, the first source connection pipes SCP1, the second source connection pipes SCP2, and the third source connection pipes SCP3 may be alternately arranged in the first direction D1.

The third source pipe SP3 may be spaced apart from the first source pipe SP1 and the second source pipe SP2. For example, the third source pipe SP3 may be spaced apart from the first source pipe SP1 in the second direction D2, and may be spaced apart from the second source pipe SP2 in a direction opposite to the second direction D2. The third source pipe SP3 may extend in the first direction D1. The third source pipe SP3 may include a third injection part I3 and a third exhaust part E3 spaced apart from the third injection part I3 in the first direction DR1. For example, the third injection part I3 may be disposed on a first end of the third source pipe SP3, and the third exhaust part E3 may be disposed on a second end facing the first end of the third source pipe SP3. A valve may be installed on each of the third injection part I3 and the third exhaust part E3. The valve may be open or closed. In an embodiment, a third source gas SG3 may be injected into the third source pipe SP3 through the third injection part I3, and the third source gas SG3 may be exhausted from the third source pipe SP3 through the third exhaust part E3.

The third source pipe SP3 may be connected to each of the third source connection pipes SCP3. Accordingly, the third source gas SG3 injected through the third injection part I3 may be injected into each of the third source connection pipes SCP3. For example, the third source gas SG3 may be injected into each of the third source connection pipes SCP3 in the second direction D2 and in the direction opposite to the second direction D2. The valve installed on the third injection part I3 may be opened, and the valve installed on the third exhaust part E3 may be closed.

Each of the third source connection pipes SCP3 may include the fourth spray nozzles NZ4. The fourth spray nozzles NZ4 may be repeatedly arranged in the second direction D2. Each of the fourth spray nozzles NZ4 may spray the third source gas SG3 in the third direction D3. For example, the third source gas SG3 injected into each of the third source connection pipes SCP3 through the third source pipe SP3 may be sprayed into the chamber CB through the fourth spray nozzles NZ4.

In an embodiment, the third spray nozzles NZ3 may not overlap (or offset) the first source connection pipes SCP1, the second source connection pipes SCP2, and the third source connection pipes SCP3 in a plan view. For example, each of the third spray nozzles NZ3 may be disposed between the first source connection pipe SCP1, the second source connection pipe SCP2, and the third source connection pipe SCP3 adjacent to each other in a plan view. For example, the third spray nozzles NZ3 may be disposed between the first spray nozzle NZ1, the second spray nozzle NZ2, and the fourth spray nozzle NZA adjacent to each other in a plan view.

Although FIG. 19 illustrates that the shower head 200 includes three source pipes SP1, SP2, and SP3, the disclosure is not limited thereto. For example, the shower head 200 may include four or more source pipes.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for treating a substrate, the apparatus comprising:
a first gas pipe extending in a first direction and including:
a first injection part; and
a first exhaust part;
a second gas pipe extending in the first direction, spaced apart from the first gas pipe in a second direction intersecting the first direction, and including:
a second injection part; and
a second exhaust part;
a plurality of first gas connection pipes extending in the second direction, connected to the first gas pipe, and spaced apart from each other in the first direction;
a plurality of second gas connection pipes extending in the second direction, connected to the second gas pipe, and spaced apart from each other in the first direction; and
a gas supply disposed adjacent to the plurality of first gas connection pipes and the plurality of second gas connection pipes.

2. The apparatus of claim 1, wherein the plurality of first gas connection pipes and the plurality of second gas connection pipes are alternately arranged in the first direction.

3. The apparatus of claim 1, wherein
each of the plurality of first gas connection pipes includes a plurality of first spray parts that spray a first gas in a third direction intersecting each of the first direction and the second direction, and
each of the plurality of second gas connection pipes includes a plurality of second spray parts that spray a second gas in the third direction.

4. The apparatus of claim 3, wherein the gas supply includes a plurality of third spray parts that spray a third gas in the third direction.

5. The apparatus of claim 4, wherein each of the plurality of third spray parts does not overlap the plurality of first gas connection pipes and the plurality of second gas connection pipes in a plan view.

6. The apparatus of claim 5, wherein each of the plurality of third spray parts is disposed between one of the plurality of first gas connection pipes and one of the plurality of second gas connection pipes adjacent to each other in a plan view.

7. The apparatus of claim 1, wherein each of the first gas pipe and the second gas pipe is disposed on the plurality of first gas connection pipes and the plurality of second gas connection pipes.

8. The apparatus of claim 1, wherein the gas supply is disposed on the plurality of first gas connection pipes and the plurality of second gas connection pipes.

9. The apparatus of claim 4, further comprising:
at least one third gas pipe extending in the first direction, spaced apart from the first gas pipe and the second gas pipe in the second direction, and including a third injection part and a third exhaust part; and
a plurality of third gas connection pipes extending in the second direction, connected to the at least one third gas pipe, and spaced apart from each other in the first direction.

10. The apparatus of claim 9, wherein the plurality of first gas connection pipes, the plurality of second gas connection pipes, and the plurality of third gas connection pipes are alternately arranged in the first direction.

11. The apparatus of claim 9, wherein each of the plurality of third spray parts does not overlap the plurality of first gas connection pipes, the plurality of second gas connection pipes, and the plurality of third gas connection pipes in a plan view.

12. A method for treating a substrate, the method comprising:
a first injection step of injecting a first gas into a first gas pipe;
a second injection step of injecting a purge gas into the first gas pipe after the first injection step;
a third injection step of injecting a second gas into a gas supply disposed adjacent to the first gas pipe after the second injection step; and
a fourth injection step of injecting the purge gas into the gas supply after the third injection step.

13. The method of claim 12, wherein the first, second, third, and fourth injection steps are repeatedly performed.

14. The method of claim 12, wherein
the first injection step further includes injecting the purge gas into a second gas pipe facing the first gas pipe and the gas supply, and
the injecting of the first gas into the first gas pipe and the injecting of the purge gas into the second gas pipe and the gas supply are performed simultaneously in the first injection step.

15. The method of claim 12, wherein
the second injection step further includes:
exhausting the first gas from the first gas pipe; and
injecting the purge gas into a second gas pipe facing the first gas pipe and the gas supply, and
the exhausting of the first gas from the first gas pipe and the injecting of the purge gas into the first gas pipe, the second gas pipe, and the gas supply are performed simultaneously in the second injection step.

16. The method of claim 12, wherein
the third injection step further includes injecting the purge gas into the first gas pipe and a second gas pipe facing the first gas pipe, and
the injecting of the purge gas into the first gas pipe and the second gas pipe and the injecting of the second gas into the gas supply are performed simultaneously in the third injection step.

17. The method of claim 12, wherein
the fourth injection step further includes:
injecting the purge gas into the first gas pipe and a second gas pipe facing the first gas pipe; and
exhausting the second gas from the gas supply, and
the injecting of the purge gas into the first gas pipe, the second gas pipe, and the gas supply and the exhausting of the second gas from the gas supply are performed simultaneously in the fourth injection step.

18. The method of claim 12, wherein
the first gas and the purge gas injected into the first gas pipe are sprayed through a plurality of first gas connection pipes connected to the first gas pipe and a plurality of first spray parts included in the plurality of first gas connection pipes, and
the second gas and the purge gas injected into the gas supply are sprayed through a plurality of second spray parts included in the gas supply.

19. The method of claim 18, further comprising:
a fifth injection step of injecting a third gas into a second gas pipe facing the first gas pipe after the fourth injection step.

20. The method of claim 19, wherein the third gas injected into the second gas pipe is sprayed through a plurality of second gas connection pipes connected to the second gas pipe and a plurality of third spray parts included in the plurality of second gas connection pipes.
